(19) United States
(12) Patent Application Publication
(10) Pub. No.: US 2024/0250084 A1
(43) Pub. Date: Jul. 25, 2024

(54) METHOD FOR OPTIMIZING PROTECTION CIRCUITS OF ELECTRONIC DEVICE CHIPS IN A WAFER

(71) Applicant: INNOSCIENCE (SUZHOU) SEMICONDUCTOR CO., LTD., Suzhou City (CN)

(72) Inventors: Jheng-Sheng YOU, Suzhou City (CN); Weixing DU, Suzhou City (CN)

(21) Appl. No.: 17/923,595

(22) PCT Filed: Jun. 28, 2022
(86) PCT No.: PCT/CN2022/101998

§ 371 Date: Nov. 6, 2022

(51) Int. Cl. H01L 27/02; H01L 21/8252; H01L 21/8258

(52) U.S. Cl. CPC H01L 27/0266; H01L 21/8252; H01L 21/8258

(57) ABSTRACT

A method for wafer-level optimization of protection circuits of nitride-based electronic device chips in a wafer is provided. The method comprises: fabricating an adjustment circuit in the wafer for each of the protection circuits, the adjustment circuit including one or more fuse elements connected respectively in parallel with one or more protection devices in the protection circuit; and adjusting each of the protection circuits by trimming one or more to-be-trimmed fuse elements corresponding to the protection circuit. The trimming of the to-be-trimmed fuse elements is performed by applying a photoresist layer on the wafer; patterning the photoresist layer with a one-to-one photomask to expose the to-be-trimmed fuse elements; and etching away the to-be-trimmed fuse elements. By using the one-to-one photomask, complete wafer coverage can be achieved without stepping the wafer repeatedly from position to position for exposure. Therefore, complexity of photomask alignment and exposure errors can be greatly reduced.

### FIELD OF THE INVENTION

The present invention generally relates to relates to a method for optimizing protection circuits of electronic device chips in a wafer. More specifically, the present invention relates to a method for wafer-level optimization of protection circuits of nitride-based electronic device chips in a wafer.

### BACKGROUND OF THE INVENTION

Wide bandgap materials, such as gallium nitride (GaN) have been widely used for high-power and high-frequency devices because of their low power loss and fast switching transition in comparison with silicon (Si) metal oxide semiconductor (MOS) materials. For example, GaN field effect transistors (FET) have been widely used in making power devices in fast chargers for mobile devices. As nitride-based transistors have lower threshold voltages, they are vulnerable to high voltage damages such as electrostatic discharges (ESD). Conventionally, a nitride-based transistor Qm may be protected with a protection circuit as shown in FIG. 1. The protection circuit may include a discharge-control transistor QDIS and a number of rectifiers D1, D2, . . . connected in series between the gates of the main transistor and the discharge-control transistor. The threshold voltage of the discharge-control transistor QDIS should be controlled to be in a desired range to ensure the effectiveness of the protection circuit. If the threshold voltage of the discharge-control transistor is too high, the protection circuit cannot be activated in time to protect the main transistor from over-voltage damages. If the threshold voltage of the discharge-control transistor is too low, the discharge-control transistor will be easily broken through. Besides, the number of rectifiers required depends on the threshold voltage of the main transistor Qm. Typically, the higher the threshold voltage of the main transistor Qm, the greater number of the rectifiers is required. With the increase of wafer size, it is difficult to maintain uniform processing conditions and parameters across wafer, resulting in threshold voltage non-uniformity. For example, under a same design value, transistors formed in central region of a wafer may have lower threshold voltages than those formed in peripheral region of the wafer.

### SUMMARY OF THE INVENTION

One objective of the present invention is to provide a cost-effective approach to address the above-said issues of non-uniform threshold voltage distribution within a wafer so as to improve the fabrication yield.

In according with one aspect of the present disclosure, a method for wafer-level optimization of protection circuits of nitride-based electronic device chips in a wafer is provided. The method comprises: fabricating an adjustment circuit in the wafer for each of the protection circuits, the adjustment circuit including one or more fuse elements connected respectively in parallel with one or more protection devices in the protection circuit; and adjusting each of the protection circuits by trimming one or more to-be-trimmed fuse elements corresponding to the protection circuit. The trimming of the to-be-trimmed fuse elements is performed by applying a photoresist layer on the wafer; patterning the photoresist layer with a one-to-one (1:1) photomask to expose the to-be-trimmed fuse elements; and etching away the to-be-trimmed fuse elements.

By using the 1:1 photomask, complete wafer coverage can be achieved without stepping the wafer repeatedly from position to position under an optical column. Therefore, complexity of photomask alignment can be greatly reduced and exposure errors can be minimized.

### BRIEF DESCRIPTION OF THE DRAWINGS

Aspects of the present disclosure may be readily understood from the following detailed description with reference to the accompanying figures. The illustrations may not necessarily be drawn to scale. That is, the dimensions of the various features may be arbitrarily increased or reduced for clarity of discussion. There may be distinctions between the artistic renditions in the present disclosure and the actual apparatus due to manufacturing processes and tolerances. For simplicity, common reference numerals may be used throughout the drawings and the detailed description to indicate the same or similar components.

FIG. 1 shows circuit diagram of a typical protection circuit of an electronic device chip in a wafer;

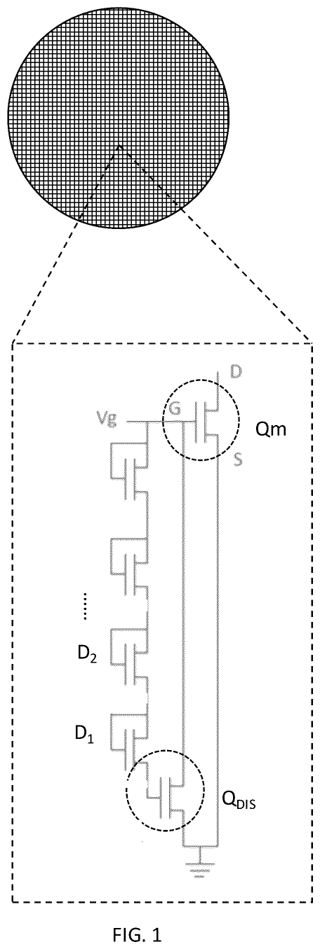

FIG. 2 shows a flowchart of a method for wafer-level optimization of protection circuits of nitride-based electronic device chips in a wafer according to some embodiments of the present invention;

FIG. 3 shows exemplary circuits of nitride-based electronic device chips in a wafer before performing the method for wafer-level optimization of protection circuits according to some embodiments of the present invention; and

FIG. 4 shows exemplary circuits of nitride-based electronic device chips in a wafer after performing the method for wafer-level optimization of protection circuits according to some embodiments of the present invention.

### DETAILED DESCRIPTION

In the following description, preferred examples of the present disclosure will be set forth as embodiments which are to be regarded as illustrative rather than restrictive. Specific details may be omitted so as not to obscure the present disclosure; however, the disclosure is written to enable one skilled in the art to practice the teachings herein without undue experimentation.

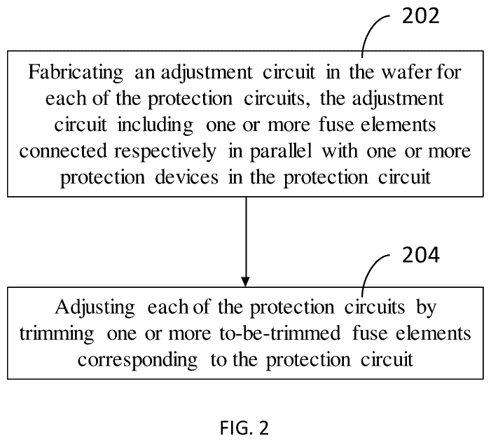

FIG. 2 shows a flowchart of a method for wafer-level optimization of protection circuits of nitride-based electronic device chips in a wafer according to some embodiments of the present invention. Each nitride-based electronic device chip may include a nitride-based main transistor and a protection circuit configured for protecting the nitride-based main transistor from high voltage damages. For example, the protection circuit may be a ESD protection circuit configured for protecting the transistor from ESD damages. The protection circuit may include a discharge-control transistor and a plurality of protection devices connected in series between the gates of the main transistor and the discharge-control transistor.

As shown in FIG. 2, the method may comprise the following steps:

S202: fabricating an adjustment circuit in the wafer for each of the protection circuits, the adjustment circuit including one or more fuse elements connected respectively in parallel with one or more protection devices in the protection circuit;

S204: adjusting each of the protection circuits by trimming one or more to-be-trimmed fuse elements corresponding to the protection circuit.

In some embodiments, the trimming of to-be-trimmed fuse elements may be performed by: applying a photoresist layer on the wafer; patterning the photoresist layer with a one-to-one (1:1) photomask (i.e., with a 1× photomask magnification), to expose the to-be-trimmed fuse elements; and etching away the to-be-trimmed fuse elements.

The 1:1 photomask is formed to expose the to-be-trimmed fuse elements based on a threshold voltage distribution of the wafer. In particular, the wafer may be divided into one or more regions based on the threshold voltage distribution. Accordingly, the photomask can be formed such that quantity of to-be-trimmed fuse elements for a protection circuit in a region including transistors of lower threshold voltage is greater than quantity of to-be-trimmed fuse elements for a protection circuit in a region including transistors of higher threshold voltage.

In some embodiments, the trimming of the to-be-trimmed fuse elements may be performed just after forming the fuse elements. In some embodiments, the trimming of the to-be-trimmed fuse elements may be performed after depositing a passivation layer on top of fuse elements. As such, structures other that those to-be-trimmed fuse elements can be protected by the passivation layer during the trimming process.

In some embodiments, the fuse elements may be made of polysilicon. In some embodiments, the fuse elements may be made of metals including, but not limited to, titanium (Ti), Tantalum (Ta), tungsten (W), aluminum (Al), cobalt (Co), cuprum (Cu), nickel (Ni), platinum (Pt), plumbum (Pb), molybdenum (Mo) and compounds (for example but not limited to, titanium nitride (TlN), tantalum nitride (TaN), other conductive nitrides or conductive oxides) thereof, metal alloys (for example aluminum copper alloy (Al—Cu)), or other proper materials.

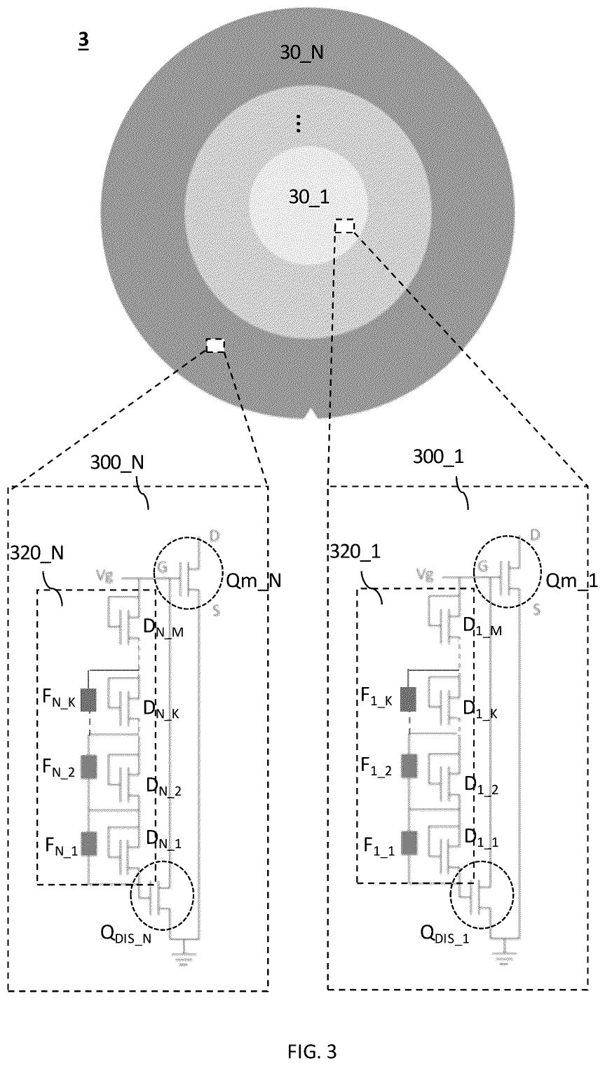

FIG. 3 shows exemplary circuits of nitride-based electronic device chips in a wafer 3 before performing the method for wafer-level optimization of protection circuits according to some embodiments of the present invention. As shown in FIG. 3, the wafer 3 may be divided into one or more regions 30_1, . . . , 30_N, based on a threshold voltage distribution, where N is the number of regions. For example, the region 30_1 may include a plurality of electronic device chips 300_1, each comprising a nitride-based main transistor Qm_1, the region 30_2 may include a plurality of electronic device chips 300_2, each comprising a nitride-based main transistor Qm_2, . . . , and the region 30_N may include a plurality of electronic device chips 300_N, each comprising a nitride-based main transistor Qm_N.

The threshold voltage distribution of the wafer may be a function of distance from the center of the wafer. For example, the nitride-based main transistor Qm_1 in the region 30_1, which is located within a central area of the wafer, may have a relatively low threshold voltage Vth1. The nitride-based main transistor Qm_N in the region 30_N, which is located in an outermost peripheral area of the wafer, may have a relatively high threshold voltage VthN.

In some embodiments, the relationship between the threshold voltage values Vth_i (i=1, 2, . . . , N) may be given by Vthᵢ₊₁=Vthᵢ+ΔV, where ΔV is a difference between threshold voltage value of transistors located in any two adjacent regions.

Each of the nitride-based main transistors Qm_1 may be protected with a protection circuit 320_1. The protection circuit 320_1 may include a discharge-control transistor Q_{DIS_1} and a plurality of rectifiers D_{1_1}, D_{1_2}, . . . , D_{1_M} connected in series between a gate of the main transistor Qm_1 and a gate of the discharge-control transistor Q_{DIS_1}. The plurality of rectifiers D_{1_1}, D_{1_2}, . . . , D_{1_M} may include a first rectifier D_{1_1} having an anode connected to the gate of the main transistor Qm_1 and a last rectifier D_{1_M} having a cathode connected to the gate of the discharge-control transistor Q_{DIS_1}.

Each of the electronic device chips 300_1 may further have an adjustment circuit including one or more fuse elements F_{1_1}, F_{1_2}, . . . , F_{1_K} connected respectively in parallel with one or more rectifiers in the protection circuit, where K is the number of fuse elements. In some embodiments, K may be equal to M, that is, all of the rectifiers D_{1_1}, D_{1_2}, . . . , D_{1_M} are connected respectively in parallel with a fuse element for circuit optimization. In other embodiments, K may be less than M, that is, only a portion of the rectifiers D_{1_1}, D_{1_2}, . . . , D_{1_M} are connected respectively in parallel with a fuse element for circuit optimization.

Similarly, each of the nitride-based main transistors Qm_N may be protected with a protection circuit 320_N. The protection circuit 320_N may include a discharge-control transistor Q_{DIS_N} and one or more rectifiers D_{N_1}, D_{N_2}, . . . , D_{N_M} connected in series between a gate of the main transistor Qm_N and a gate of the discharge-control transistor Q_{DIS_N}. The plurality of rectifiers D_{N_1}, D_{N_2}, . . . , D_{N_M} may include a first rectifier D_{N_1} having an anode connected to the gate of the main transistor Qm_N and a last rectifier D_{N_M} having a cathode connected to the gate of the discharge-control transistor Q_{DIS_N}.

Each of the electronic device chips 300_N may have an adjustment circuit including one or more fuse elements F_{N_1}, F_{N_2}, . . . , F_{N_K} connected respectively in parallel with one or more rectifiers in the protection circuit, where K is the number of fuse elements. In some embodiments, K may be equal to M, that is, all of the rectifiers D_{N_1}, D_{N_2}, . . . , D_{N_M} are connected respectively in parallel with a fuse element for circuit optimization. In other embodiments, K may be less than M, that is, only a portion of the rectifiers D_{N_1}, D_{N_2}, . . . , D_{N_M} are connected respectively in parallel with a fuse element for circuit optimization.

In some embodiments, each of the main transistors may be a AlGaN/GaN enhancement-mode (E-mode) high-electron-mobility transistor (HEMT).

In some embodiments, each of the discharge-control transistors may be a AlGaN/GaN enhancement-mode (E-mode) high-electron-mobility transistor (HEMT).

In some embodiments, each of the rectifiers may comprise a transistor having a gate being shorted with a source to act as an anode of the rectifier and a drain to act as a cathode of the rectifier. Each of the transistors may be a AlGaN/GaN enhancement-mode (E-mode) high-electron-mobility transistor (HEMT).

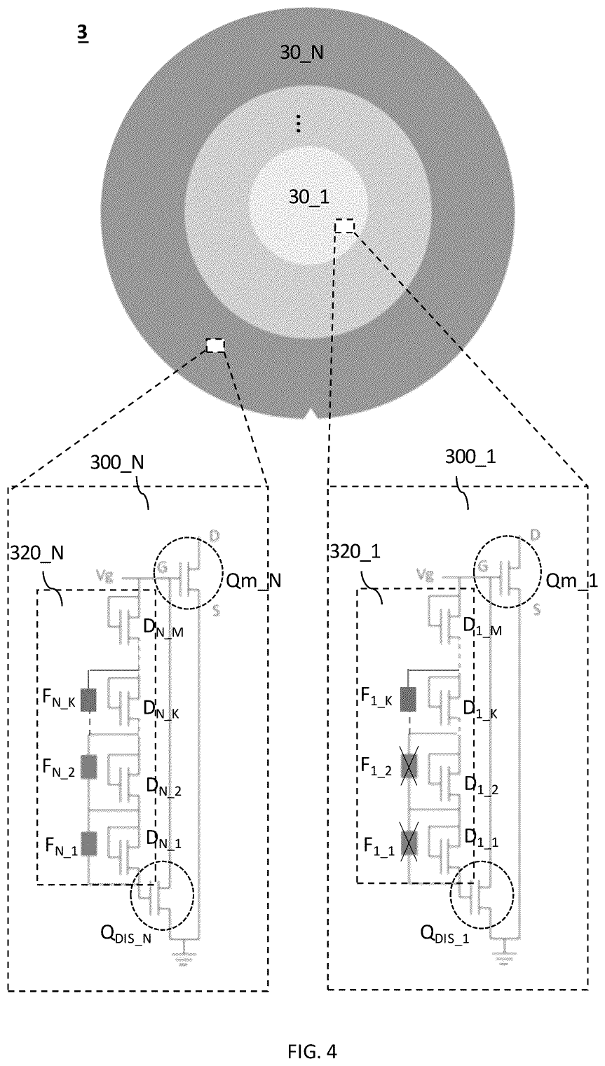

FIG. 4 shows exemplary circuits of nitride-based electronic device chips in the wafer 3 after performing the method for wafer-level optimization of protection circuits. As shown, no fuse elements have been trimmed in the protection circuit 302_N for protecting the transistor Qm_N while two fuse elements F_{1_1} and F_{1_2} are removed or etched away from the protection circuit 302_1 for protecting the transistor Qm_1 which has a threshold voltage lower than the transistor Qm_N.

As it can be seen from the examples in FIGS. 3 and 4, by performing the method for wafer-level optimization of protection circuits, each of the protections circuits is adjusted such that quantity of trimmed fuse elements for a protection circuit in a region including transistors of lower threshold voltage is greater than quantity of trimmed fuse elements for a protection circuit in a region including transistors of higher threshold voltage. It should be understood that the exemplary circuits illtreated in FIGS. 3 and 4 are for illustrative purpose only. The number of to-be-trimmed fuse elements for each protection circuit can be any suitable number.

The embodiments were chosen and described in order to best explain the principles of the invention and its practical application, thereby enabling others skilled in the art to understand the invention for various embodiments and with various modifications that are suited to the particular use contemplated. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations. While the apparatuses disclosed herein have been described with reference to particular structures, shapes, materials, composition of matter and relationships . . . etc., these descriptions and illustrations are not limiting. Modifications may be made to adapt a particular situation to the objective, spirit and scope of the present disclosure. All such modifications are intended to be within the scope of the claims appended hereto.

1. A method for wafer-level optimization of protection circuits of nitride-based electronic device chips in a wafer, comprising:
fabricating an adjustment circuit in the wafer for each of the protection circuits, the adjustment circuit including one or more fuse elements connected respectively in parallel with one or more protection devices in the protection circuit; and
adjusting each of the protection circuits by trimming one or more to-be-trimmed fuse elements corresponding to the protection circuit; and
wherein the trimming of the to-be-trimmed fuse elements is performed by:
applying a photoresist layer on the wafer;
patterning the photoresist layer with a one-to-one photomask to expose the to-be-trimmed fuse elements; and
etching away the to-be-trimmed fuse elements.

2. The method according to claim 1, wherein the one-to-one photomask is formed on basis of a threshold voltage distribution of the wafer.

3. The method according to claim 2, wherein:
the wafer is divided into one or more regions based on the threshold voltage distribution; and
the one-to-one photomask is formed such that quantity of to-be-trimmed fuse elements for a protection circuit in a region including transistors of lower threshold voltage is greater than quantity of to-be-trimmed fuse elements for a protection circuit in a region including transistors of higher threshold voltage.

4. The method according to claim 1, wherein each of the protection devices is a rectifier.

5. The method according to claim 4, wherein the rectifier is constituted with a transistor having a gate being connected with a source to act as an anode of the rectifier and a drain to act as a cathode of the rectifier.

6. The method according to claim 1, wherein each of the fuse elements is made of polysilicon.

7. The method according to claim 1, wherein each of the fuse elements is made of a metal.

8. A nitride-based semiconductor wafer, comprising:
a plurality of nitride-based electronic device chips, each comprising:
a main transistor;
a protection circuit for protecting the main transistor, the protection circuit comprising a discharge-control transistor and a number of protection devices connected in series between a gate of the main transistor and a gate of the discharge-control transistor; and
an adjustment circuit including one or more fuse elements connected respectively in parallel with one or more protection devices in the protection circuit:
wherein
the wafer is divided into one or more regions based on a threshold voltage distribution; and
each of the plurality of protection circuits is adjusted such that quantity of trimmed fuse elements for a protection circuit in a region including transistors of lower threshold voltage is greater than quantity of trimmed fuse elements for a protection circuit in a region including transistors of higher threshold voltage.

9. The nitride-based semiconductor wafer according to claim 8, wherein each of protection devices is a rectifier.

10. The nitride-based semiconductor wafer according to claim 9 wherein the rectifier is constituted with a transistor having a gate being connected with a source to act as an anode of the rectifier and a drain to act as a cathode of the rectifier.

11. The nitride-based semiconductor wafer according to claim 8, wherein each of the fuse elements is made of polysilicon.

12. The nitride-based semiconductor wafer according to claim 8, wherein each of the fuse elements is made of a metal.

13. The nitride-based semiconductor wafer according to claim 8, wherein each of the main transistors is a nitride-based high-electron-mobility transistor (HEMT).

14. The nitride-based semiconductor wafer according to claim 13, wherein the nitride-based HEMT is a nitride-based enhancement-mode (E-mode) HEMT.

15. The nitride-based semiconductor wafer according to claim 14, wherein the nitride-based E-mode HEMT is a AlGaN/GaN E-mode HEMT.

16. The nitride-based semiconductor wafer according to claim 8, wherein each of the discharge-control transistors is a nitride-based high-electron-mobility transistor (HEMT).

17. The nitride-based semiconductor wafer according to claim 16, wherein the nitride-based HEMT is a nitride-based enhancement-mode (E-mode) HEMT.

18. The nitride-based semiconductor wafer according to claim 17, wherein the nitride-based E-mode HEMT is a AlGaN/GaN E-mode HEMT.
